(19) United States
(12) Patent Application Publication
(10) Pub. No.: US 2026/0180545 A1
(43) Pub. Date: Jun. 25, 2026

(54) ACOUSTIC WAVE SYSTEM WITH INTERMEDIATE STRUCTURE

(71) Applicant: Skyworks Solutions, Inc., Irvine, CA (US)

(72) Inventors: Cedric Olivier Gerald Poirel, Irvine, CA (US); David Albert Feld, Los Altos, CA (US); Michael David Hill, Emmitsburg, MD (US); Rei Goto, Osaka-Shi (JP)

(21) Appl. No.: 19/379,596

(22) Filed: Nov. 4, 2025

Related U.S. Application Data
(60) Provisional application No. 63/716,423, filed on Nov. 5, 2024.
(60) Provisional application No. 63/716,407, filed on Nov. 5, 2024.
(60) Provisional application No. 63/716,421, filed on Nov. 5, 2024.

(51) Int. Cl. H03H 9/02

(52) U.S. Cl. CPC H03H 9/02834

(57) ABSTRACT

An acoustic wave system includes a multi-layer piezoelectric substrate including a support substrate, a piezoelectric layer, and an intermediate structure between the support substrate and the piezoelectric layer. The intermediate structure can include a first dielectric material in a first region, and the first dielectric material and a second dielectric material can be included in a second region. A first resonator is in the first region, and a second resonator is in the second region.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to multilayer piezoelectric substrate (MPS) surface acoustic wave (SAW) devices.

### Description of Related Technology

A communications device such as a mobile phone, uses a filter device to separate signals having different bands, such as a transmission signal and a reception signal, for example. A surface acoustic wave (SAW) filter that includes a SAW element (e.g., SAW resonator) is an example of the filter device. The SAW resonator includes an interdigital transducer (IDT) electrode formed on a piezoelectric layer. The SAW filter can be provided as a ladder-type filter, a double mode SAW (DMS) filter, and the like.

### SUMMARY

In some aspects, the techniques described herein relate to an acoustic wave system having a first region and a second region, the acoustic wave system including: a multi-layer piezoelectric substrate including a support substrate, a piezoelectric layer, and an intermediate structure between the support substrate and the piezoelectric layer, the intermediate structure including a first dielectric material in the first region, and the first dielectric material and a second dielectric material in the second region; a first resonator in the first region; and a second resonator in the second region.

In some aspects, the techniques described herein relate to an acoustic wave system wherein a temperature coefficient of frequency of the second dielectric material is greater than a temperature coefficient of frequency of the first dielectric material.

In some aspects, the techniques described herein relate to an acoustic wave system wherein a hardness of the second dielectric material is greater than a hardness of the first dielectric material.

In some aspects, the techniques described herein relate to an acoustic wave system wherein the first dielectric material includes silicon oxide.

In some aspects, the techniques described herein relate to an acoustic wave system wherein the second dielectric material has a temperature coefficient of frequency greater than silicon oxide.

In some aspects, the techniques described herein relate to an acoustic wave system wherein the second dielectric material includes tellurium oxide, germanium oxide, tantalum oxide, silicon nitride silicon oxynitride, aluminum nitride, silicon carbide, or sapphire.

In some aspects, the techniques described herein relate to an acoustic wave system wherein the second dielectric material includes air.

In some aspects, the techniques described herein relate to an acoustic wave system wherein the second resonator is a multimode surface acoustic wave resonator.

In some aspects, the techniques described herein relate to an acoustic wave system wherein the second dielectric material is positioned between the first dielectric layer and the piezoelectric layer.

In some aspects, the techniques described herein relate to an acoustic wave system wherein the second dielectric material is positioned between the first dielectric layer and the support substrate.

In some aspects, the techniques described herein relate to an acoustic wave system further including a trap-rich layer between the support substrate and the intermediate structure.

In some aspects, the techniques described herein relate to an acoustic wave system wherein the first resonator is a surface acoustic wave resonator, and the second resonator is a bulk acoustic wave resonator.

In some aspects, the techniques described herein relate to an acoustic wave system further including an additional piezoelectric layer in the first region.

In some aspects, the techniques described herein relate to an acoustic wave system wherein the intermediate structure further includes a third dielectric layer in the first region.

In some aspects, the techniques described herein relate to an acoustic wave system having a first region and a second region, the acoustic wave system including: a multi-layer piezoelectric substrate including a first stack in the first region and a second stack different from the first stack in the second region, the first stack including a support substrate, a piezoelectric layer, and a first dielectric layer between the support substrate and the piezoelectric layer, the second stack including the support substrate, the piezoelectric layer, the first dielectric layer, and a second dielectric layer between the support substrate and the piezoelectric layer; a first resonator in the first region; and a second resonator in the second region.

In some aspects, the techniques described herein relate to an acoustic wave system wherein a temperature coefficient of frequency of the second dielectric layer is greater than a temperature coefficient of frequency of the first dielectric layer.

In some aspects, the techniques described herein relate to an acoustic wave system wherein the second dielectric layer is positioned between the first dielectric layer and the piezoelectric layer.

In some aspects, the techniques described herein relate to an acoustic wave system wherein the second dielectric layer is positioned between the first dielectric layer and the support substrate.

In some aspects, the techniques described herein relate to an acoustic wave system having a first region and a second region, the acoustic wave system including: a multi-layer piezoelectric substrate including a support substrate, a piezoelectric layer, and an intermediate structure having a dielectric layer between the support substrate and the piezoelectric layer, the intermediate structure including an air cavity in the second region; a first resonator in the first region; and a second resonator in the second region.

In some aspects, the techniques described herein relate to an acoustic wave system wherein the air cavity acoustically isolates the piezoelectric layer and the dielectric layer, and the second resonator is a multimode surface acoustic wave resonator.

In some aspects, the techniques described herein relate to an acoustic wave system having a first region and a second region, the acoustic wave system including: a multi-layer piezoelectric substrate including a first stack in the first region and a second stack in the second region, the first stack including a support substrate, a first piezoelectric layer, a second piezoelectric layer, and a first dielectric layer between the support substrate and the piezoelectric layer, the second stack including the support substrate, the first piezoelectric layer, the first dielectric layer, and a second dielectric layer between the support substrate and the piezoelectric layer; a first resonator in the first region; and a second resonator in the second region.

In some aspects, the techniques described herein relate to an acoustic wave system wherein the first piezoelectric layer and the second piezoelectric layer having different materials.

In some aspects, the techniques described herein relate to an acoustic wave system wherein the first piezoelectric layer is positioned between the first dielectric layer and the second piezoelectric layer.

In some aspects, the techniques described herein relate to an acoustic wave system wherein a temperature coefficient of frequency of the second dielectric layer is greater than a temperature coefficient of frequency of the first dielectric layer.

In some aspects, the techniques described herein relate to an acoustic wave system wherein a hardness of the second dielectric layer is greater than a hardness of the first dielectric layer.

In some aspects, the techniques described herein relate to an acoustic wave system wherein the first dielectric layer includes silicon oxide, and the second dielectric layer has a temperature coefficient of frequency greater than silicon oxide.

In some aspects, the techniques described herein relate to an acoustic wave system wherein the second dielectric layer includes tellurium oxide, germanium oxide, tantalum oxide, silicon nitride silicon oxynitride, aluminum nitride, silicon carbide, or sapphire.

In some aspects, the techniques described herein relate to an acoustic wave system wherein the second dielectric layer includes air.

In some aspects, the techniques described herein relate to an acoustic wave system wherein the second resonator is a multimode surface acoustic wave resonator.

In some aspects, the techniques described herein relate to an acoustic wave system wherein the second dielectric layer is positioned between the first dielectric layer and the piezoelectric layer.

In some aspects, the techniques described herein relate to an acoustic wave system wherein the second dielectric layer is positioned between the first dielectric layer and the support substrate.

In some aspects, the techniques described herein relate to an acoustic wave system further including a trap-rich layer between the support substrate and the first dielectric layer.

In some aspects, the techniques described herein relate to an acoustic wave system having a first region and a second region, the acoustic wave system including: a first surface acoustic wave device in the first region, the first surface acoustic wave device including a support substrate, a first dielectric layer over the support substrate, a first piezoelectric layer over the first dielectric layer, a second piezoelectric layer over the first piezoelectric layer, and a first interdigital transducer electrode in electrical communication with the second piezoelectric layer; and a second surface acoustic wave device in the second region, the second acoustic wave device wave device including the support substrate, an intermediate structure over the support substrate, the first piezoelectric layer over the intermediate structure, and a second interdigital transducer electrode in electrical communication with the second piezoelectric layer, the intermediate structure having the first dielectric layer and a second dielectric layer.

In some aspects, the techniques described herein relate to an acoustic wave system wherein the first piezoelectric layer and the second piezoelectric layer having different materials.

In some aspects, the techniques described herein relate to an acoustic wave system wherein a temperature coefficient of frequency of the second dielectric layer is greater than a temperature coefficient of frequency of the first dielectric layer.

In some aspects, the techniques described herein relate to an acoustic wave system wherein a hardness of the second dielectric layer is greater than a hardness of the first dielectric layer.

In some aspects, the techniques described herein relate to an acoustic wave system wherein the second dielectric layer is positioned between the first dielectric layer and the piezoelectric layer.

In some aspects, the techniques described herein relate to an acoustic wave system wherein the second dielectric layer is positioned between the first dielectric layer and the support substrate.

In some aspects, the techniques described herein relate to an acoustic wave system having a first region and a second region, the acoustic wave system including: a first surface acoustic wave device in the first region, the first surface acoustic wave device including a support substrate, a first dielectric layer over the support substrate, a first piezoelectric layer over the first dielectric layer, a second piezoelectric layer over the first piezoelectric layer, and a first interdigital transducer electrode in electrical communication with the second piezoelectric layer; and a second surface acoustic wave device in the second region, the second acoustic wave device wave device including the support substrate, an intermediate structure over the support substrate, the first piezoelectric layer over the intermediate structure, and a second interdigital transducer electrode in electrical communication with the second piezoelectric layer, the intermediate structure having the first dielectric layer and an air cavity formed in the first dielectric layer.

In some aspects, the techniques described herein relate to an acoustic wave system wherein the air cavity is poisoned between the first dielectric layer and the first piezoelectric layer, the second surface acoustic wave device is a multimode surface acoustic wave resonator.

In some aspects, the techniques described herein relate to an acoustic wave system including: a surface acoustic wave device including a first portion of a piezoelectric layer and an interdigital transducer electrode in electrical communication with the first portion of the piezoelectric layer; and a bulk acoustic wave device including a first electrode, a second electrode, and a second portion of the piezoelectric layer between the first electrode and the second electrode.

In some aspects, the techniques described herein relate to an acoustic wave system wherein the first portion and the second portion of the piezoelectric layer includes different materials.

In some aspects, the techniques described herein relate to an acoustic wave system wherein the first portion of the piezoelectric layer includes lithium niobate or lithium tantalate.

In some aspects, the techniques described herein relate to an acoustic wave system wherein the second portion of the piezoelectric layer includes aluminum nitride.

In some aspects, the techniques described herein relate to an acoustic wave system wherein the piezoelectric layer includes a conductive via electrically connected to the first electrode of the bulk acoustic wave device.

In some aspects, the techniques described herein relate to an acoustic wave system further including a support substrate and an intermediate structure between the support substrate and the piezoelectric layer.

In some aspects, the techniques described herein relate to an acoustic wave system wherein the intermediate structure includes an acoustic reflector between the second portion of the piezoelectric layer and the support substrate.

In some aspects, the techniques described herein relate to an acoustic wave system wherein the acoustic reflector includes an air cavity.

In some aspects, the techniques described herein relate to an acoustic wave system wherein the acoustic reflector includes an acoustic Bragg reflector.

In some aspects, the techniques described herein relate to an acoustic wave system wherein the intermediate structure includes a first dielectric layer and a second dielectric layer.

In some aspects, the techniques described herein relate to an acoustic wave system wherein a temperature coefficient of frequency of the second dielectric layer is greater than a temperature coefficient of frequency of the first dielectric layer.

In some aspects, the techniques described herein relate to an acoustic wave system wherein a hardness of the second dielectric layer is greater than a hardness of the first dielectric layer.

In some aspects, the techniques described herein relate to an acoustic wave system wherein the first dielectric layer includes silicon oxide.

In some aspects, the techniques described herein relate to an acoustic wave system wherein the second dielectric layer includes tellurium oxide, germanium oxide, tantalum oxide, silicon nitride silicon oxynitride, aluminum nitride, silicon carbide, or sapphire.

In some aspects, the techniques described herein relate to an acoustic wave system wherein the second dielectric layer includes air.

In some aspects, the techniques described herein relate to an acoustic wave system having a first region and a second region, the acoustic wave system including: a multi-layer piezoelectric substrate including a support substrate, a piezoelectric layer, an intermediate structure between the support substrate and the piezoelectric layer, the intermediate structure including an acoustic reflector in the second region; a surface acoustic wave device in the first region; and a bulk acoustic wave device in the second region.

In some aspects, the techniques described herein relate to an acoustic wave system wherein the piezoelectric layer includes a first portion in the first region and a second portion in the second region, the first and second portions of the piezoelectric layer includes different materials.

In some aspects, the techniques described herein relate to an acoustic wave system wherein the first portion of the piezoelectric layer includes lithium niobate or lithium tantalate, and the second portion of the piezoelectric layer includes aluminum nitride.

In some aspects, the techniques described herein relate to an acoustic wave system wherein the acoustic reflector includes an air cavity or an acoustic Bragg reflector.

In some aspects, the techniques described herein relate to an acoustic wave system having a first region and a second region, the acoustic wave system including: a multi-layer piezoelectric substrate including a support substrate, a piezoelectric layer having a first portion and a second portion, an intermediate structure between the support substrate and the piezoelectric layer, the intermediate structure including an air cavity in the first region and an acoustic reflector in the second region; a surface acoustic wave device in the first region; and a bulk acoustic wave device in the second region.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a schematic top-plan view of the SAW device of FIG. 1A.

FIG. 2A is a schematic cross-sectional side view of a SAW device according to another embodiment.

FIG. 2B is a schematic top-plan view of the SAW device of FIG. 2A.

FIG. 3A is a schematic cross-sectional side view of a SAW device according to another embodiment.

FIG. 3B is a schematic top-plan view of the SAW device of FIG. 3A.

FIG. 4A is a schematic cross-sectional side view of a SAW device according to another embodiment.

FIG. 4B is another schematic cross-sectional side view of the SAW device.

FIG. 5A is a schematic cross-sectional side view of an acoustic wave device according to another embodiment.

FIG. 5B is a schematic top-plan view of the acoustic wave device of FIG. 5A.

FIG. 5C is a schematic cross-sectional side view of the acoustic wave device of FIG. 5B.

FIG. 6A is a schematic cross-sectional side view of an acoustic wave device according to another embodiment.

FIG. 6B is a schematic cross-sectional side view of an acoustic wave device according to another embodiment.

FIG. 7 is a schematic diagram of a radio frequency module that includes a surface acoustic wave resonator according to an embodiment.

FIG. 8 is a schematic diagram of a radio frequency module that includes filters with surface acoustic wave resonators according to an embodiment.

FIG. 9 is a schematic block diagram of a module that includes an antenna switch and duplexers that include a surface acoustic wave resonator according to an embodiment.

FIG. 10A is a schematic block diagram of a module that includes a power amplifier, a radio frequency switch, and duplexers that include a surface acoustic wave resonator according to an embodiment.

FIG. 10B is a schematic block diagram of a module that includes filters, a radio frequency switch, and a low noise amplifier according to an embodiment.

FIG. 11A is a schematic block diagram of a wireless communication device that includes a filter with a surface acoustic wave resonator in accordance with one or more embodiments.

FIG. 11B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

An acoustic wave system, such as an acoustic wave filter, can include a plurality of acoustic wave devices to process acoustic waves. The acoustic wave devices can include surface acoustic wave devices and/or bulk acoustic wave devices. A multi-band acoustic wave filter is an example of the acoustic wave system and is an electronic device that can selectively filter or pass specific frequency bands in a signal. The multi-band acoustic wave filter can operate at multiple frequency bands to filter and separate different signals. A surface acoustic wave (SAW) filter, a bulk acoustic wave (BAW) filer, and a hybrid acoustic wave filter that includes one or more acoustic wave devices and one or more bulk acoustic wave devices are examples of the multi-band acoustic wave filter.

The SAW filter can incorporate multiple interdigital transducers (IDTs) that operate at two or more different resonant frequencies. The design and arrangement of the IDTs can at least in part determine a frequency response of the SAW filter. Multiple sets of IDTs with different spacing and electrode configurations can be used to create multiple resonant frequencies, enabling the filter to operate across multiple frequency bands. The BAW filter uses a resonant structure that includes a thin film between two electrodes, creating an acoustic standing wave in the bulk of the material. The frequency response of the BAW filter can be influenced by the thickness of this film, as well as the materials used. By tuning these characteristics, BAW filters can achieve high-quality filtering over a wide range of frequencies. Unlike SAW filters, which operate primarily on the surface, BAW filters are well-suited for higher frequencies, as they leverage bulk acoustic wave propagation, providing robust performance across various frequency bands. Multi-band SAW and/or BAW filters can be implemented in various wireless communication systems, such as mobile phones, Wi-Fi devices, and radar systems.

Filter size reduction can be important for module floor planning and cost reduction. A multi-band filter can be formed in a single die for filter size reduction. However, optimum electrical properties (e.g., coupling factor k², temperature coefficient of frequency (TCF), etc.) of acoustic elements can be different. In multilayer piezoelectric substrate devices that includes a piezoelectric layer and one or more additional layers, electrical properties can be dependent on a stack configuration (e.g., thicknesses and materials of the layers of the multilayer piezoelectric substrate). Therefore, it can be challenging to form a plurality of acoustic wave elements in a single die. Also, integrating both SAW and BAW devices into a single filter presents significant challenges due to the different resonant mechanisms and different structures.

Various embodiments disclosed herein relate to acoustic wave systems that includes a plurality of acoustic wave resonators having different stack configurations. Some embodiments disclosed herein relate to multilayer piezoelectric substrate (MPS) devices, such as MPS surface acoustic wave (SAW) devices, that include two or more acoustic elements formed in a single die. The MPS devices can be multi-band MPS devices, such as a multi-band filter. Some embodiments disclosed herein relate to hybrid acoustic wave systems (e.g., hybrid filters) that include a SAW device and a BAW device. An acoustic wave system according to some embodiments can have a first region and a second region. The acoustic wave system can include an MPS including a support substrate, a piezoelectric layer, and an intermediate structure between the support substrate and the piezoelectric layer. The intermediate structure can include a first dielectric material in the first region, and the first dielectric material and a second dielectric material in the second region. A first resonator can be positioned in the first region, and a second resonator can be positioned in the second region. The first resonator and the second resonator can be any combination of two SAW resonators, two BAW resonators, or a pair of a SAW resonator and a BAW resonator.

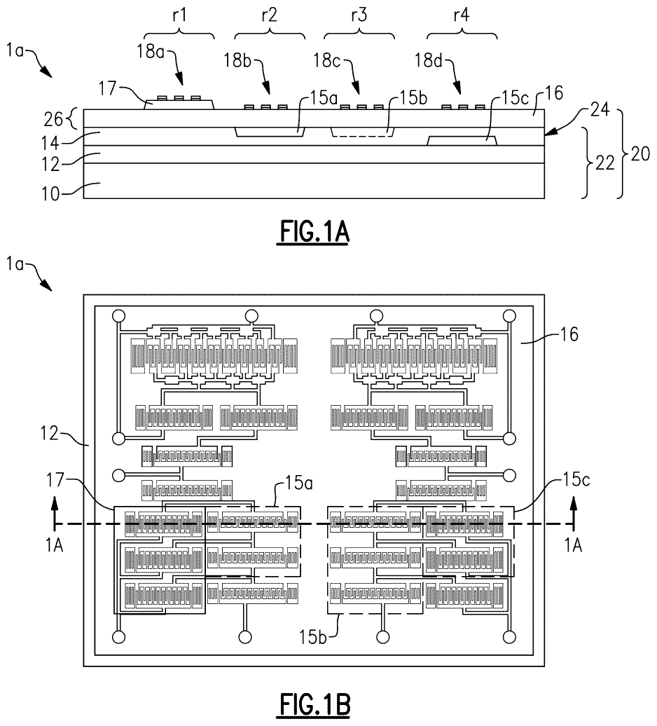

FIG. 1A is a schematic cross-sectional side view of a surface acoustic wave (SAW) device 1a according to an embodiment. FIG. 1B is a schematic top-plan view of the SAW device 1a of FIG. 1A. The SAW device 1a is an example of an acoustic wave system. The SAW device 1a can be a SAW filter.

The SAW device 1a can include a support substrate 10, a trap rich layer 12, a functional layer 14, dielectric layers 15a, 15b, 15c, a piezoelectric layer 16, an additional piezoelectric layer 17, and acoustic elements including first to forth interdigital transducer (IDT) electrodes 18a, 18b, 18c, 18d. The first IDT electrode 18a is positioned in a first region r1, the second IDT electrode 18b is positioned in a second region r2, the third IDT electrode 18c is positioned in a third region r3, and the fourth IDT electrode is positioned in a fourth region r4. The functional layer 14 and the dielectric layers 15a, 15b, 15c can together define an intermediate structure 24. The piezoelectric layer 16 and the additional piezoelectric layer 17 can together define a piezoelectric structure 26. The support substrate 10, the trap rich layer 12, the intermediate structure 24, and the piezoelectric structure 26 can together define a multilayer piezoelectric substrate (MPS) 20, and the support substrate 10, the trap rich layer 12, the intermediate structure 24 can together define a support substrate structure 22 of the MPS 20. The first to fourth IDT electrodes 18a, 18b, 18c, 18d together with the MPS 20 in the respective regions r1 to r4 can define different resonators. In FIG. 1A, the number of fingers of the acoustic elements is reduced in FIG. 1A for illustration purposes.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high impedance. An acoustic impedance of the support substrate 10 can be higher than an acoustic impedance of the piezoelectric layer 16 and the additional piezoelectric layer 17. For instance, the support substrate 10 can have a higher acoustic impedance than an acoustic impedance of lithium niobate and a higher acoustic impedance than lithium tantalate.

The trap rich-layer 12 can be formed at, near, on, or with the support substrate 10. In some embodiments, the trap rich-layer 12 can mitigate the parasitic surface conductivity of the support substrate 10. The trap rich-layer 12 can be formed in a number of ways, for example, by forming the surface of the support substrate 10 with amorphous or polycrystalline silicon, by forming the surface of the support substrate 10 with porous silicon, or by introducing defects into the surface of the support substrate 10 via ion implantation, ion milling, or other methods. In some embodiments, the trap-rich layer 12 can improve the electrical characteristics of the SAW device 1a by increasing the depth and sharpness on the anti-resonance peak.

The functional layer 14 can be positioned between the trap rich layer 12 and the piezoelectric layer 16. The functional layer 14 can be a dielectric layer, such as an oxide layer (e.g., silicon oxide (SiO₂) layer, or silicon nitride (SiN), or silicon oxynitride SiON, or a multi-layer structure of two or more of these). The functional layer 14 can enhance energy confinement and TCF tunability. In some embodiments, the functional layer 14 can be a single crystal layer arranged to confine acoustic energy and lower a higher frequency spurious response.

The dielectric layers 15a, 15b, 15c can be positioned at any suitable positions between the piezoelectric layer 16 and the support substrate 10. In some embodiments, the dielectric layers 15a, 15b, 15c can be formed in or embedded in the functional layer 14. In the illustrated embodiment, the dielectric layer 15a is positioned in the second region r2, the dielectric layer 15b is positioned in the third region r3, and the dielectric layer 15c is positioned in the fourth region r4. The dielectric layer 15a is positioned closer to the piezoelectric layer 16 than to the trap-rich layer 12. For example, the dielectric layer 15a can be in physical contact with the piezoelectric layer 16. Likewise, the dielectric layer 15b is positioned closer to the piezoelectric layer 16 than to the trap-rich layer 12. For example, the dielectric layer 15b can be in physical contact with the piezoelectric layer 16. The dielectric layer 15c is positioned closer to the trap-rich layer 12 then to the piezoelectric layer 16. For example, the dielectric layer 15c can be in physical contact with the trap-rich layer 12.

The dielectric layers 15a, 15b, 15c can include any suitable dielectric materials different from the material of the functional layer 14. For example, the dielectric layers 15a, 15b, 15c can include silicon oxide (e.g., SiO₂), tellurium oxide (e.g., TeO₂), germanium oxide (e.g., GeO₂), tantalum oxide (e.g., Ta₂O₅), silicon nitride silicon oxynitride (e.g., SiON), aluminum nitride (e.g., AlN), silicon carbide (e.g., SiC), sapphire, or a dielectric gas (e.g., air in the form of an air cavity).

The materials of the functional layer 14 and the dielectric layers 15a, 15b, 15c included in the intermediate structure 24 can affect the performance of the resonators formed in the respective regions. For example, the temperature coefficient of frequency (TCF) of a resonator can be shifted by including the dielectric layer 15a, 15b, 15c that has a different TCF from the functional layer 14. By shifting the TCF, the higher order modes can be shifted. Therefore, in some embodiments, by adding the dielectric layer 15a, 15b, 15c with a higher TCF than the TCF of the functional layer 14, the higher order modes can be separated more from the fundamental mode as compared to a resonator that does not include the dielectric layer 15a, 15b, 15c. More distance between the higher order modes and the fundamental mode can reduce influence on the fundamental mode from the higher order modes. Similarly, the TCF of the resonator can be shifted by including the dielectric layer 15a, 15b, 15c that has a different hardness from the functional layer 14. In some embodiments, by adding the dielectric layer 15a, 15b, 15c with a greater hardness than the hardness of the functional layer 14, the higher order modes can be separated more from the fundamental mode as compared to a resonator that does not include the dielectric layer 15a, 15b, 15c.

When an air gap is provided as a dielectric layer (e.g., as the dielectric layer 15b) in a manner that acoustically isolates the piezoelectric layer 16 from the functional layer 14, a Lamb wave device may be formed. Using the Lamb wave may improve the non-linearity performance of the resonator. Including an air gap may be beneficial for higher frequency applications. When the air cavity has a relatively thin thickness, the higher order mode may be shifted to a significantly higher frequency as compared to a thicker air cavity. It can be beneficial for a resonator close to the antenna node (e.g., a resonator closest to the antenna node, a resonator second closest to the antenna node, or a resonator third closest to the antenna node) to maintain signal clarity, stability, or quality. Also, an airgap may be suited for resonators that do not call for power durability, such as a multi-mode SAW (e.g., a double mode surface acoustic wave (DMS) device). While a gas cavity (e.g., the air cavity) or an acoustically isolative layer can be more preferred for Lamb wave and DMS devices and/or receive filer components, including a solid dielectric material or a material that is acoustically non-isolative can be more preferred for non-Lamb wave and high-power devices and/or transmit filter components.

The materials and the locations of the dielectric layers 15a, 15b, 15c can be selected based at least in part on the desired TCF, quality factor Q, coupling coefficient k2, and/or wave type. The locations of the dielectric layers 15a, 15b, 15c can relate to the magnitude of the effect provided by the dielectric layers 15a, 15b, 15c. For example, when a material with a higher TCF than the TCF of the functional layer is provided as the dielectric layer 15a, 15b, the TCF can shift to a lower value and the quality factor Q may be improved as compared to when the material is provided as the dielectric layer 15c.

In some embodiments, the dielectric layer 15a can be a silicon nitride layer or a silicon oxynitride layer, the dielectric layer 15b can be an air gap, and the dielectric layer 15c can be a silicon nitride layer or a silicon oxynitride layer. Any suitable number of dielectric layers can be provided in any suitable locations of the SAW device 1a.

The piezoelectric layer 16 can include lithium tantalate (LT). For example, the piezoelectric layer 16 can be an LT layer having a cut angle of 20° (20° Y-cut X-propagation LT) or a cut angle of 60° (60° Y-cut X-propagation LT). For example, the piezoelectric layer 16 can be 20±10° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 16. For example, the piezoelectric layer 16 can be an LN layer having a cut angle of about 118° (118° Y-cut X-propagation LN) or more or a cut angle of about 132° (132Y-cut X-propagation LN) or less. For example, the piezoelectric layer 16 can be 125±20° Y-cut LN, 125±15° Y-cut LN, 125±10° Y-cut LN, or 125±5° Y-cut LN. In some embodiments, use of the LN layer in the piezoelectric layer 16 can provide an improved coupling coefficient.

The additional piezoelectric layer 17 can include the same material or a different material as the piezoelectric layer 16. For example, the additional piezoelectric layer 17 can include an LT layer or an LN layer. The piezoelectric layer 16 can be referred to as a first piezoelectric layer and the additional piezoelectric layer 17 can be referred to as a second piezoelectric layer. When the piezoelectric layer 16 and the additional piezoelectric layer 17 have the same material, the piezoelectric layer 16 and the associated piezoelectric layer 17 may have a unitary structure. When the piezoelectric layer 16 and the additional piezoelectric layer 17 have different materials, the piezoelectric layer 16 and the associated piezoelectric layer 17 can be separate layers with an interface therebetween.

A sidewall of the additional piezoelectric layer 17 can be sloped. An angle of the slope relative to an upper surface of the piezoelectric layer 16 can be greater than zero and less than 90°. For example, the angle of the slope relative to the upper surface of the piezoelectric layer 16 can be in a range between 15° and 89°, 15° and 75°, 25° and 75°, 35° and 75°, 25° and 65°, 35° and 75°, or 35° and 65°. The sloped sidewall can function as an acoustic obstruction structure for the first IDT electrode 18a or between adjacent acoustic elements (e.g., the first IDT electrode 18a and the second IDT electrode 18b). For example, the sloped sidewall can reflect acoustic energy in a direction that can prevent or mitigate unwanted reflection back to the first IDT electrode 18a. In some embodiments, other types of acoustic obstruction structures can be implemented in addition to or in place of the sloped sidewall. For example, the acoustic obstruction structures disclosed at least in U.S. Patent Publication No. 2023/0006636, the entire contents of which are incorporated by reference herein in their entirety and for all purposes.

The thickness and/or the material of the piezoelectric structure 26 can relate to electrical properties (e.g., coupling factor k², temperature coefficient of frequency (TCF), etc.) of the SAW device 1a. Accordingly, the electrical properties of the first IDT electrode 18a and the second IDT electrode 18b can be tuned by the different thicknesses and/or materials of the piezoelectric layer 16 and the additional piezoelectric layer 17.

The IDT electrodes (e.g., the first to fourth IDT electrodes 18a-18d) can include any suitable material(s). The IDT electrodes may include one or more metals, such as aluminum (Al), copper (Cu), Magnesium (Mg), titanium (Ti), tungsten (W), molybdenum (Mo), etc. The IDT electrodes may include alloys, such as AlMgCu, AlCu, etc. In some embodiments, the IDT electrodes can have a multi-layer IDT electrode that includes more than two layers. For example, the IDT electrodes can include first and second layers. The first layer can include molybdenum (Mo) and the second layer can include aluminum (Al) in certain embodiments. The first IDT electrode 18a can be in electrical communication with the additional piezoelectric layer 17 and the piezoelectric layer 16 in the first region r1. The second IDT electrode 18b can be in electrical communication with the piezoelectric layer 16 in the second region r2. The third IDT electrode 18c can be in electrical communication with the piezoelectric layer 16 in the second region r3. The fourth IDT electrode 18d can be in electrical communication with the piezoelectric layer 16 in the fourth region r4.

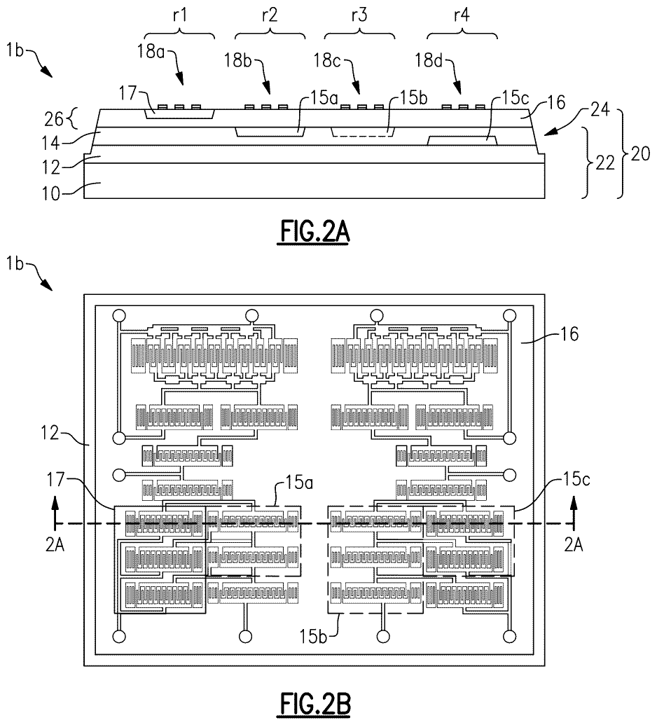

In FIGS. 1A and 1B, the upper surface of the additional piezoelectric layer 17 is raised relative to the upper surface of the piezoelectric layer 16. However, in some embodiments, the upper surface of the piezoelectric layer 16 and the upper surface of the additional piezoelectric layer 17 can be flush or coplanar with each other as shown in, for example, FIGS. 2A and 2B.

FIG. 2A is a schematic cross-sectional side view of a surface acoustic wave (SAW) device 1b according to an embodiment. FIG. 2B is a schematic top-plan view of the SAW device 1b of FIG. 2A. Unless otherwise noted, components of FIGS. 2A and 2B can be the same as or generally similar to the like components disclosed herein, such as those shown in FIGS. 1A and 1B. The SAW device 1b is generally similar to the SAW device 1a of FIGS. 1A and 1B. Unlike the SAW device 1a, the SAW device 1b has a flat upper piezoelectric structure surface and a portion of the additional piezoelectric layer 17 is disposed in a recess formed in the piezoelectric layer 16. The flat upper piezoelectric structure surface of the piezoelectric structure 26 can be beneficial for an IDT electrode forming process.

As described herein, the air cavity formed as a dielectric layer in the intermediate structure 24 can be beneficial for low power devices such DMS devices. Therefore, in some embodiments, air cavities can be provided below the DMS components in an acoustic wave system.

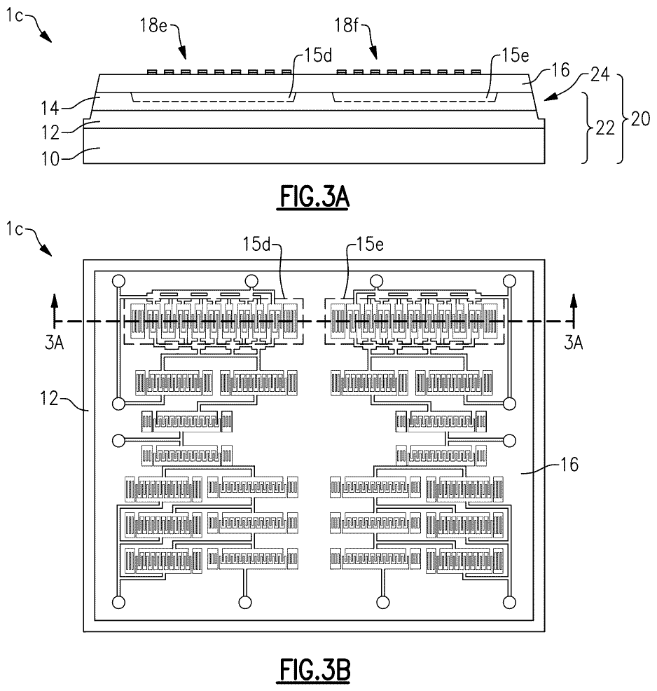

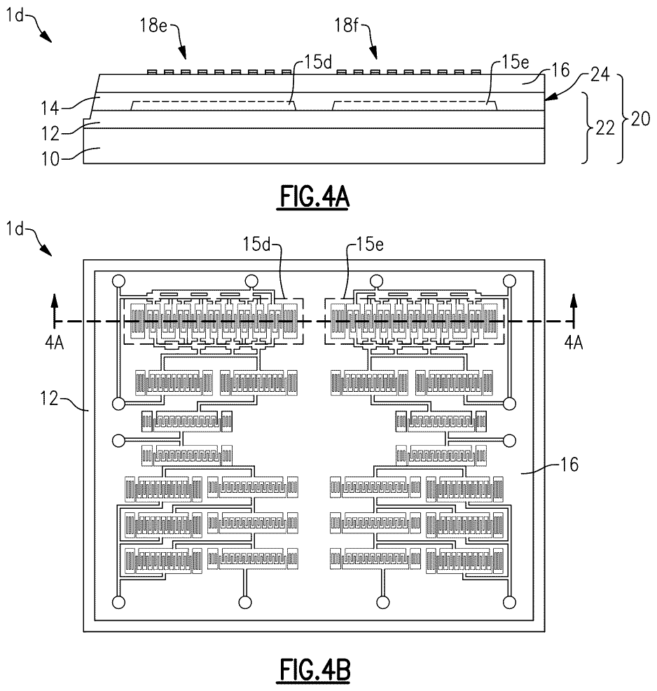

FIG. 3A is a schematic cross-sectional side view of a surface acoustic wave (SAW) device 1c according to an embodiment. FIG. 3B is a schematic top-plan view of the SAW device 1c of FIG. 3A. FIG. 4A is a schematic cross-sectional side view of a surface acoustic wave (SAW) device 1d according to an embodiment. FIG. 4B is a schematic top-plan view of the SAW device 1d of FIG. 4A. Unless otherwise noted, components of FIGS. 3A-4B can be the same as or generally similar to the like components disclosed herein, such as those shown in FIGS. 1A to 2B.

The SAW devices 1c, 1d can include a support substrate 10, a trap rich layer 12, an intermediate structure 24 including a functional layer 14 and air cavities 15d, 15e, a piezoelectric layer 16, and multimode SAW elements 18e, 18f. The air cavities 15d, 15e are provided between the functional layer 14 and the piezoelectric layer 16 in FIGS. 3A and 3B, and the air cavities 15d, 15e are provided between the functional layer 14 and the trap-rich layer 12 in FIGS. 4A and 4B. The air cavities 15d, 15e can provide a better wave trapping ability than without the air cavities 15d, 15e for the multimode SAW elements 18e, 18f, which can relate to a higher coupling coefficient k² and a higher quality factor Q. When the air cavities 15d, 15e are provided between the functional layer 14 and the trap-rich layer 12, the TCF can be improved as compared to when air cavities 15d, 15e are provided between the functional layer 14 and the piezoelectric layer 16 due to the temperature compensation with the functional layer 14.

FIGS. 1A-4B show SAW devices 1a-1d that include only SAW components. However, any suitable principles and advantages disclosed herein can be implemented with any suitable types of acoustic wave components. For example, the intermediate structure 24 and/or the piezoelectric structure 26 disclosed herein can be implemented in a hybrid acoustic wave system that includes SAW components and BAW components.

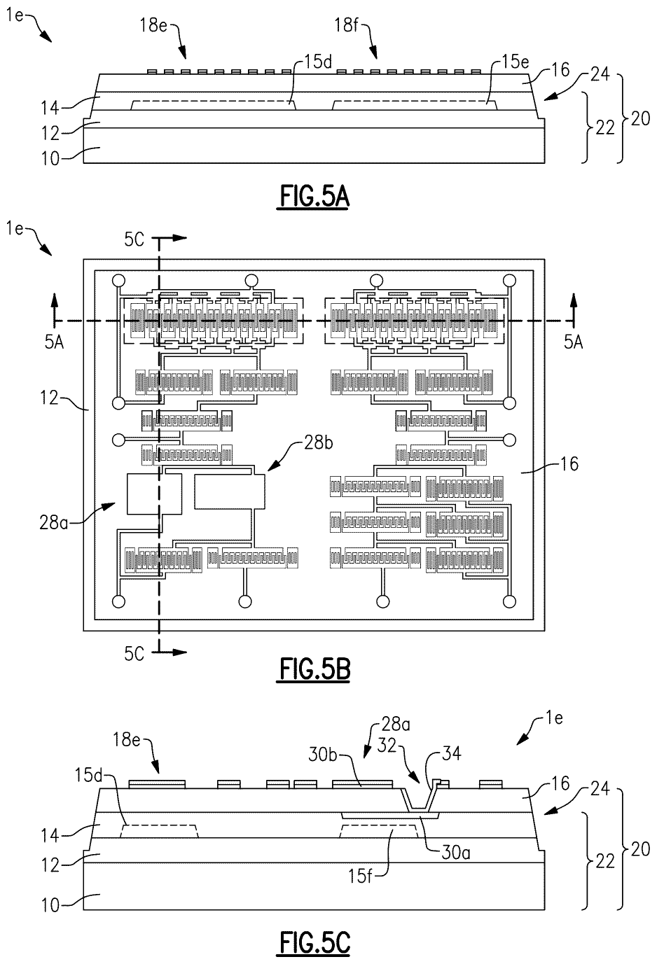

FIG. 5A is a schematic cross-sectional side view of an acoustic wave device 1e according to an embodiment. FIG. 5B is a schematic top-plan view of the acoustic wave device 1e of FIG. 5A. FIG. 5C is a schematic cross-sectional side view of the acoustic wave device 1e according to an embodiment. FIG. 4B is another schematic cross-sectional side view of the SAW device 1e. Unless otherwise noted, components of FIGS. 5A-5C can be the same as or generally similar to the like components disclosed herein, such as those shown in FIGS. 1A to 4B. The acoustic wave device 1e is an example of a hybrid acoustic wave system that includes one or more SAW components and one or more BAW components.

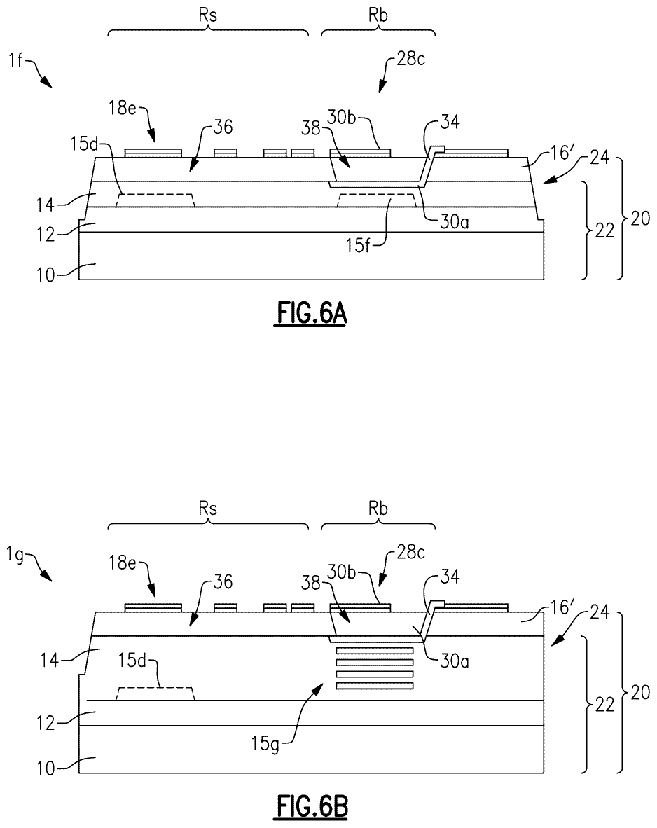

The acoustic wave device 1e can share various similarities with the SAW device 1d shown in FIGS. 4A and 4B. The acoustic wave device 1e can include BAW devices 28a, 28b. The BAW devices 28a, 28b can each include a pair of electrodes and an acoustic reflector. FIG. 5C illustrates a first electrode 30a and a second electrode 30b as the pair of electrodes, and an air cavity 15f as the acoustic reflector of the BAW device 28a. The acoustic wave device 1e can include a via 32 that provides an electrical pathway between the first electrode 30a and an upper surface of the piezoelectric layer 16. The via 32 can extend through a thickness of the piezoelectric layer 16. The via 32 can be a conformal via that includes a conductive layer 34 conformally provided in the via 32. In some other embodiments, the via 32 can be a filled via. The BAW device 28a can be a film bulk acoustic wave resonator (FBAR). In some other embodiments, there can be a solid acoustic mirror in place of the air cavity 15f as shown in FIG. 6B and such a BAW device can be a BAW solidly mounted resonator (SMR).

A material of a piezoelectric layer in a SAW device may be different from a material of a piezoelectric layer in a BAW device. Accordingly, a hybrid acoustic wave system that includes one or more SAW components and one or more BAW components can have a piezoelectric layer that has different materials in different regions.

FIG. 6A is a schematic cross-sectional side view of an acoustic wave device 1f according to an embodiment. Unless otherwise noted, components of FIG. 6A can be the same as or generally similar to the like components disclosed herein, such as those shown in FIGS. 1A to 5C. The structure shown in FIG. 6A is generally similar to the structure shown in FIG. 5C. The acoustic wave device 1f can include a SAW region Rs and a BAW region Rb. A BAW device 28c can be formed in the BAW region Rb.

The piezoelectric layer 16′ can include a first portion that includes a first piezoelectric material 36 and a second portion that includes a second piezoelectric material 38. The first portion can be in the SAW region Rs and the second portion can be in the BAW region Rb. The first piezoelectric material 36 can be a material suitable for a SAW device and the second piezoelectric material 38 can be a material suitable for a BAW device. For example, the first piezoelectric material 36 can be LN or LT. The second piezoelectric material 38 can include a material such as, but not limited to, aluminum nitride (AlN), zinc oxide (ZnO), or lead zirconium titanate (PZT). In certain applications, the second piezoelectric material 38 can be an AlN layer. The second piezoelectric material 38 can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the second piezoelectric material 38 can be AlN based layer doped with Sc. Doping the second piezoelectric material 38 can adjust the resonant frequency. Doping the second piezoelectric material 38 can increase the electromechanical coupling coefficient (kt²) of the BAW device 28c.

FIG. 6B is a schematic cross-sectional side view of an acoustic wave device 1g according to an embodiment. Unless otherwise noted, components of FIG. 6B can be the same as or generally similar to the like components disclosed herein, such as those shown in FIGS. 1A to 6A. The structure shown in FIG. 6B is generally similar to the structure shown in FIG. 5A. In the acoustic wave device 1g in FIG. 6B, a solid acoustic wave mirror 15g is provided in place of the air cavity 15f of the acoustic wave device 1f in FIG. 6A.

The solid acoustic wave mirror 15g includes an acoustic Bragg reflector. The illustrated acoustic Bragg reflector can include alternating low impedance layers and high impedance layers. In some embodiments, the material of the functional layer 14 can be the low impedance layer, and additional layers can be provided as the high impedance layer. As an example, the Bragg reflectors can include alternating silicon dioxide layers as low impedance layers and tungsten layers as high impedance layers. Any other suitable features of an SMR can alternatively or additionally be implemented.

The hybrid acoustic wave systems disclosed herein can implement one or more SAW devices and one or more BAW devices without significantly increasing the overall size of the system. Any suitable combination(s) of the features disclosed herein can be implemented in a single system. For example, various features of the piezoelectric structure and/or various features of the intermediate structure can be combined in a single acoustic wave system.

The acoustic wave devices disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

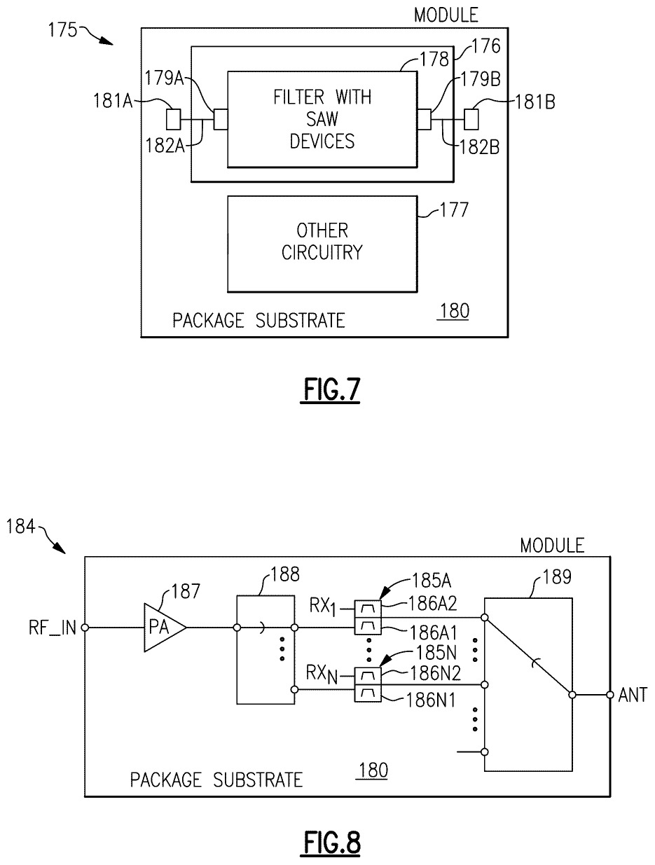

FIG. 7 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW devices with any suitable combination of features of the SAW devices disclosed herein. The SAW component 176 can include a SAW die that includes one or more MMS filters and/or one or more SAW resonators.

The SAW component 176 shown in FIG. 7 includes a filter 178 and terminals 179A and 179B. The filter 178 includes SAW devices. One or more of the SAW devices can be implemented in accordance with any suitable principles and advantages disclosed herein. In some other embodiments, the filter 178 can include one or more BAW devices. One or more SAW devices and one or more BAW devices can be implemented in the filter 178 in accordance with any suitable principles and advantages disclosed herein.

The terminals 179A and 178B can serve, for example, as an input contact and an output contact. The SAW component 176 and the other circuitry 177 are on a common packaging substrate 180 in FIG. 7. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 8 is a schematic diagram of a radio frequency module 184 that includes an acoustic wave device or system according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more acoustic wave devices in accordance with any suitable principles and advantages disclosed herein. Similarly, one or more of the receive filters 186A2 to 186N2 can include one or more acoustic wave devices in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

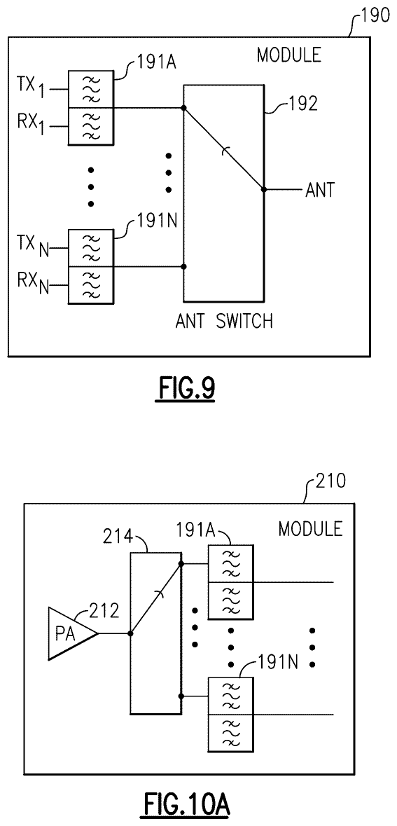

FIG. 9 is a schematic block diagram of a module 190 that includes duplexers 191A to 191N and an antenna switch 192. One or more filters of the duplexers 191A to 191N can include any suitable number of acoustic wave devices in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190. MMS filters disclosed herein can be implemented in receive filters of one or more of the duplexers 191A to 191N, for example.

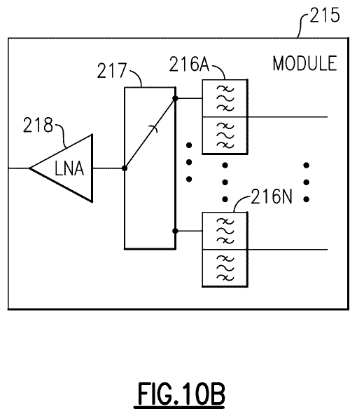

FIG. 10A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of acoustic wave devices in accordance with any suitable principles and advantages discussed herein. Any suitable number of duplexers 191A to 191N can be implemented.

FIG. 10B is a schematic block diagram of a module 215 that includes filters 216A to 216N, a radio frequency switch 217, and a low noise amplifier 218 according to an embodiment. One or more filters of the filters 216A to 216N can include any suitable number of MMS filters and/or acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

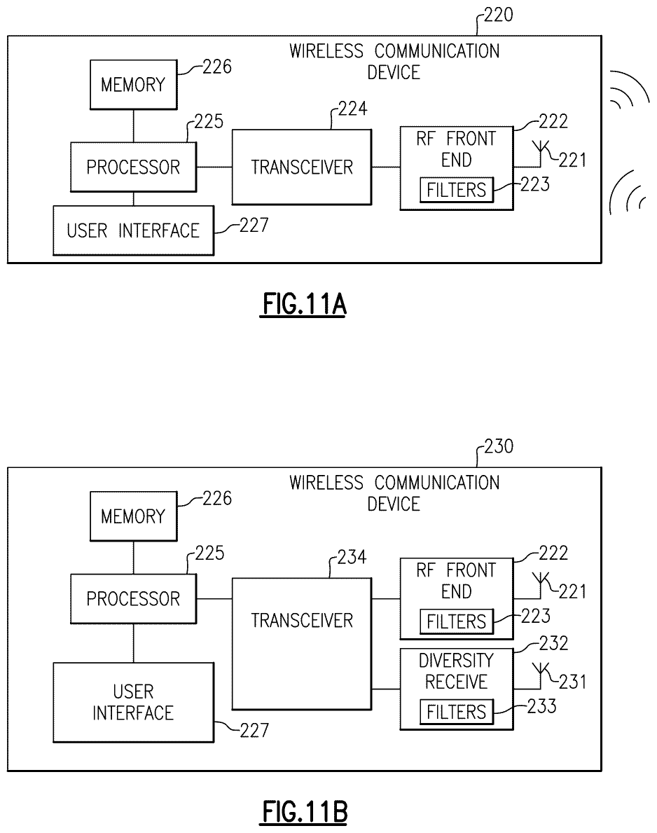

FIG. 11A is a schematic diagram of a wireless communication device 220 that includes filters 223 in a radio frequency front end 222 according to an embodiment. The filters 223 can include one or more acoustic wave devices in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include acoustic wave devices that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 11B is a schematic diagram of a wireless communication device 230 that includes filters 223 in a radio frequency front end 222 and a second filter 233 in a diversity receive module 232. The wireless communication device 230 is like the wireless communication device 200 of FIG. 11A, except that the wireless communication device 230 also includes diversity receive features. As illustrated in FIG. 11B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more acoustic wave devices that include any suitable combination of features discussed with reference to any embodiments discussed above. The diversity module 232 and the radio frequency front end 222 can together be considered part of a radio frequency front end.

Although embodiments disclosed herein relate to surface acoustic wave filters and/or resonators, any suitable principles and advantages disclosed herein can be applied to other types of acoustic wave devices that include an IDT electrode, such as Lamb wave devices and/or boundary wave devices. For example, any suitable combination of features of the acoustic velocity adjustment structures disclosed herein can be applied to a Lamb wave device and/or a boundary wave device.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An acoustic wave system having a first region and a second region, the acoustic wave system comprising:
a multi-layer piezoelectric substrate including a support substrate, a piezoelectric layer, and an intermediate structure between the support substrate and the piezoelectric layer, the intermediate structure including a first dielectric material in the first region, and the first dielectric material and a second dielectric material in the second region;
a first resonator in the first region; and
a second resonator in the second region.

2. The acoustic wave system of claim 1 wherein a temperature coefficient of frequency of the second dielectric material is greater than a temperature coefficient of frequency of the first dielectric material.

3. The acoustic wave system of claim 1 wherein a hardness of the second dielectric material is greater than a hardness of the first dielectric material.

4. The acoustic wave system of claim 1 wherein the first dielectric material includes silicon oxide.

5. The acoustic wave system of claim 4 wherein the second dielectric material has a temperature coefficient of frequency greater than silicon oxide.

6. The acoustic wave system of claim 1 wherein the second dielectric material includes tellurium oxide, germanium oxide, tantalum oxide, silicon nitride silicon oxynitride, aluminum nitride, silicon carbide, or sapphire.

7. The acoustic wave system of claim 1 wherein the second dielectric material includes air.

8. The acoustic wave system of claim 7 wherein the second resonator is a multimode surface acoustic wave resonator.

9. The acoustic wave system of claim 1 wherein the second dielectric material is positioned between the first dielectric material and the piezoelectric layer.

10. The acoustic wave system of claim 1 wherein the second dielectric material is positioned between the first dielectric material and the support substrate.

11. The acoustic wave system of claim 1 further comprising a trap-rich layer between the support substrate and the intermediate structure.

12. The acoustic wave system of claim 1 wherein the first resonator is a surface acoustic wave resonator, and the second resonator is a bulk acoustic wave resonator.

13. The acoustic wave system of claim 1 further comprising an additional piezoelectric layer in the first region.

14. The acoustic wave system of claim 1 wherein the intermediate structure further includes a third dielectric layer in the first region.

15. An acoustic wave system having a first region and a second region, the acoustic wave system comprising:
a multi-layer piezoelectric substrate including a first stack in the first region and a second stack different from the first stack in the second region, the first stack including a support substrate, a piezoelectric layer, and a first dielectric layer between the support substrate and the piezoelectric layer, the second stack including the support substrate, the piezoelectric layer, the first dielectric layer, and a second dielectric layer between the support substrate and the piezoelectric layer;
a first resonator in the first region; and
a second resonator in the second region.

16. The acoustic wave system of claim 15 wherein a temperature coefficient of frequency of the second dielectric layer is greater than a temperature coefficient of frequency of the first dielectric layer.

17. The acoustic wave system of claim 15 wherein the second dielectric layer is positioned between the first dielectric layer and the piezoelectric layer.

18. The acoustic wave system of claim 15 wherein the second dielectric layer is positioned between the first dielectric layer and the support substrate.

19. An acoustic wave system having a first region and a second region, the acoustic wave system comprising:
a multi-layer piezoelectric substrate including a support substrate, a piezoelectric layer, and an intermediate structure having a dielectric layer between the support substrate and the piezoelectric layer, the intermediate structure including an air cavity in the second region;
a first resonator in the first region; and
a second resonator in the second region.

20. The acoustic wave system of claim 19 wherein the air cavity acoustically isolates the piezoelectric layer and the dielectric layer, and the second resonator is a multimode surface acoustic wave resonator.
